(19) United States
(12) Patent Application Publication
(10) Pub. No.: US 2026/0293025 A1
(43) Pub. Date: Sep. 24, 2026

(54) POWER CONVERSION DEVICE AND ELECTRIC VEHICLE USING SAME

(71) Applicant: MITSUBISHI ELECTRIC MOBILITY CORPORATION, Tokyo (JP)

(72) Inventors: Naoya ABE, Tokyo (JP); Yukiko MORI, Tokyo (JP); Kengo NISHIMURA, Tokyo (JP); Koji NAKAJIMA, Tokyo (JP); Satoshi ISHIBASHI, Tokyo (JP); Isao TOTTORI, Tokyo (JP); Yoshihiro TAKESHIMA, Tokyo (JP); Toru DAIGO, Tokyo (JP); Kenta FUJII, Tokyo (JP)

(73) Assignee: MITSUBISHI ELECTRIC MOBILITY CORPORATION, Tokyo (JP)

(21) Appl. No.: 19/475,246

(22) PCT Filed: Jun. 5, 2023
(86) PCT No.: PCT/JP2023/020805

§ 371 Date: Oct. 14, 2025

(51) Int. Cl. H05K 7/14; H02M 7/00

(52) U.S. Cl. CPC H05K 7/1432; H02M 7/003

(57) ABSTRACT

A main circuit connection portion includes: a first conductor provided at a back surface of a circuit substrate; a second conductor in which current flows in a direction opposite to that in the first conductor, and provided at a front surface of the substrate and is at least partially opposed to the first conductor via the substrate; a third conductor in which current flows in the same direction as in the second conductor, and provided at the back surface of the substrate while keeping an distance from the first conductor; a fourth conductor provided in a side wall of at least one through hole formed in the substrate and connects the second and the third conductor; a relay portion filled with a thermally conductive member in the hole; and a cooling portion provided at surfaces of the first and the third conductor.

### TECHNICAL FIELD

The present disclosure relates to a power conversion device and an electric vehicle using the same.

### BACKGROUND ART

In power conversion devices used for electric vehicles such as a hybrid car and an electric automobile, larger current and higher voltage are used for size reduction and efficiency improvement. From the perspective of power module protection, low-inductance technology for main circuit wiring is necessary for reducing surge voltage occurring in switching as much as possible. It is well known that the inductance is reduced by a configuration in which conductors through which opposite currents flow are arranged so as to be opposed to each other. For example, Patent Document 1 indicates that the inductance can be reduced using wiring (pattern) in a circuit substrate.

### CITATION LIST

### Patent Document

Patent Document 1: Japanese Laid-Open Patent Publication No. 2017-220961 (paragraph [0009], FIG. 6)

### SUMMARY OF THE INVENTION

### Problem to be Solved by the Invention

However, in order to further reduce the inductance, it is necessary to reduce the distance between wires opposed to each other (P line and N line) or increase the pattern width, and such designing is limited due to constraints in structure and manufacturing. In addition, main circuit wiring through which large current flows needs to be configured such that temperature increase by heat generation in the main circuit wiring is not transferred to a component having a low heat resistance, and therefore a structure that allows cooling is also required.

The present disclosure has been made to solve the above problem, and an object of the present disclosure is to provide a power conversion device having high heat dissipation performance at low cost and easily, and an electric vehicle using the same.

### Means to Solve the Problem

A power conversion device according to the present disclosure includes: a first conductor provided at a first surface of a substrate; a second conductor in which current flows in a direction opposite to that in the first conductor, and which is provided at a second surface of the substrate and is at least partially opposed to the first conductor via the substrate; a third conductor in which current flows in the same direction as in the second conductor, and which is provided at the first surface of the substrate while keeping an insulation distance from the first conductor; a fourth conductor provided at a side wall of at least one through hole formed in the substrate and connects the second conductor and the third conductor; and a cooling portion provided at surfaces of the first conductor and the third conductor via an insulating thermally conductive material.

### Effect of the Invention

According to the present disclosure, the first conductor is opposed to the second conductor and is adjacent to the third conductor, whereby the inductance can be reduced not only at the opposed parts but also at the adjacent parts. In addition, it becomes possible to cool not only the conductor at the lower surface of the substrate but also the conductor at the front surface of the substrate via the relay portion and the conductor at the side wall of the through hole, whereby the power conversion device can be downsized.

### BRIEF DESCRIPTION OF THE DRAWINGS

FIG. 1 is a block diagram showing a configuration of a power conversion device according to embodiment 1.

FIG. 2 is a schematic perspective view showing a configuration of a main circuit connection portion of the power conversion device according to embodiment 1.

FIG. 3 is a sectional view showing a configuration of the main circuit connection portion of the power conversion device according to embodiment 1.

FIG. 4 is a schematic perspective view showing a configuration of a main circuit connection portion of a power conversion device according to embodiment 2.

FIG. 5 is a sectional view showing a configuration of the main circuit connection portion of the power conversion device according to embodiment 2.

FIG. 6 is a sectional view showing a configuration of a main circuit connection portion of a power conversion device according to embodiment 3.

FIG. 7A and FIG. 7B are sectional views showing a configuration of a main circuit connection portion of a power conversion device according to embodiment 4.

FIG. 8 is a sectional view showing a configuration of a main circuit connection portion of a power conversion device according to embodiment 5.

FIG. 9 is a sectional view showing another configuration of the main circuit connection portion of the power conversion device according to embodiment 5.

FIG. 10 shows a configuration of an electric vehicle using a power conversion device according to embodiment 6.

### DESCRIPTION OF EMBODIMENTS

### Embodiment 1

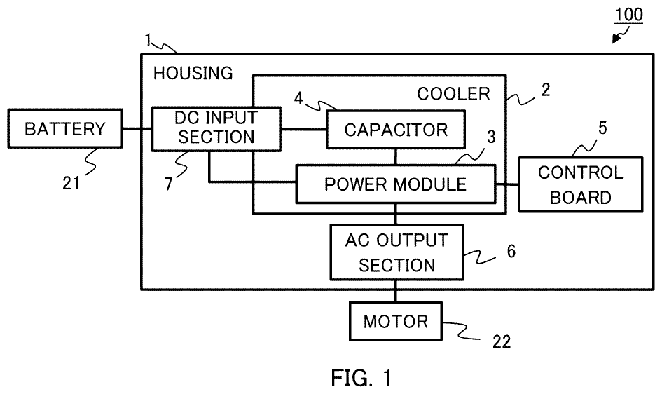

FIG. 1 is a block diagram showing a configuration of a power conversion device 100 according to embodiment 1 of the present disclosure. As shown in FIG. 1, the power conversion device 100 includes a housing 1, a cooler 2, a power module 3, a capacitor 4, a control board 5, an AC output section 6, and a DC input section 7. The cooler 2 releases heat of heat generation members, e. g., the power module, the capacitor, the AC output section, and the DC input section to the outside of the power conversion device.

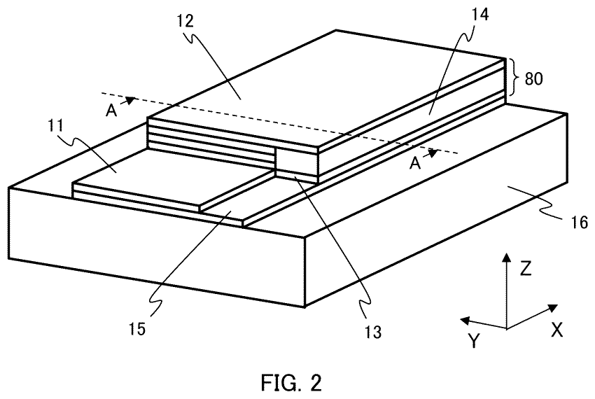

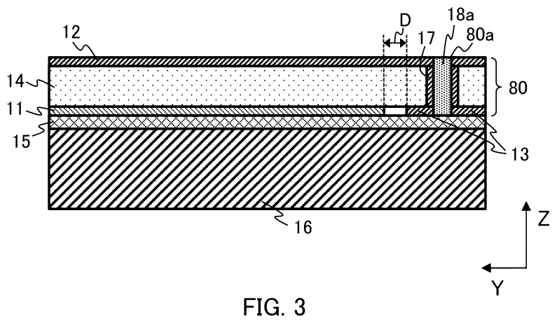

FIG. 2 is a schematic perspective view showing a configuration of a main circuit connection portion of the power conversion device 100 according to embodiment 1, and schematically shows the configuration of the main circuit connection portion between the power module and the capacitor, between the power module and the AC output section, between the power module and the DC input section, and between the DC input section and the capacitor, in the power conversion device 100 in FIG. 1. FIG. 3 is a sectional view as seen in an A-A arrow direction in FIG. 2. A main circuit wiring portion refers to high-voltage wiring from the DC input section to the capacitor, from the capacitor to the power module, and from the DC input section to the power module.

As shown in FIG. 2 and FIG. 3, in the main circuit wiring portion in embodiment 1, a circuit substrate 80 has a first conductor 11 and a second conductor 12 with a base material 14 interposed therebetween. The first conductor 11 and the second conductor 12 are formed by metal members having a high electrical conductivity and a high thermal conductivity, and made of copper or aluminum material, for example. In the present embodiment, copper is used. The base material 14 is an insulating resin.

The circuit substrate 80 has a multilayer structure and has copper patterns such as the first conductor 11, and electronic components which are not shown (components other than the main circuit wiring are not shown).

Regarding directions in which currents flow, for example, in FIG. 2, current flows through the first conductor 11 in an X direction, and current flows through the second conductor 12 in a −X direction, so that currents flow directions opposite to each other (the above may be reversed).

A third conductor 13 has the same potential phase (band) as the second conductor 12, and is provided at a back surface which is a first surface of the circuit substrate 80 which is a layer different from the second conductor 12, via the base material 14 and a relay portion 18a provided in a through hole 80a formed in the circuit substrate 80. The relay portion 18a is formed by a member having a high thermal conductivity. The third conductor 13 is located flush with the first conductor 11, and extends on the circuit substrate 80 while keeping an insulation distance D from the first conductor 11. At least one through hole 80a is formed in the circuit substrate 80.

An insulating thermally conductive material 15 is provided between a cooling portion 16 and the first conductor 11. The insulating thermally conductive material 15 has an insulation function and a heat dissipation function between the cooling portion 16, and the first conductor 11 and the third conductor 13. The insulating thermally conductive material 15 contacts with the first conductor 11 and the third conductor 13 partially or in an entire range so that parts where heat needs to be dissipated can dissipate heat to the cooling portion 16.

The first conductor 11, the third conductor 13, and a fourth conductor 17 formed at a side wall of the through hole 80a are formed by separate members, and are electrically connected when the circuit substrate 80 is formed. Unlike a case of using a busbar with a mold, the first conductor 11 and the second conductor 12 form parallel flat plates with the comparatively thin base material 14 interposed therebetween, and therefore the distance between electrodes can be made shorter than in the case of a busbar with a mold, thus providing an effect of reducing the inductance. In addition, since the first conductor 11 and the third conductor 13 are located flush with each other, parallel flat plates are formed also at a side surface part, so that the inductance is further reduced.

In cooling of a main circuit in Patent Document 1, only one surface is cooled and a surface opposite to the cooling surface merely dissipates heat via a base material and a cooling conductor. Thus, cooling cannot be actively performed and an upper surface remains having a high temperature. However, in the present disclosure, the main circuit in the upper surface layer can also dissipate heat to the cooling portion via the relay portion 18a and the fourth conductor 17, with a high thermal conductivity.

If higher cooling performance is needed, the relay portion 18a may be made of metal, whereby heat can be transferred to the cooling portion 16 more efficiently than in a case where only a side surface of the relay portion 80a is made of metal (fourth conductor 17). Since heat can be transferred to the cooling portion 16 from the second conductor 12 at a front surface which is a second surface of the circuit substrate 80, the widths of the first conductor 11 and the second conductor 12 can be reduced, and as a result, the power conversion device can be downsized.

As described above, the power conversion device 100 according to the present embodiment 1 includes: the first conductor 11 provided at the back surface of the circuit substrate 80; the second conductor 12 in which current flows in a direction opposite to that in the first conductor 11, and which is provided at the front surface of the circuit substrate 80 and is at least partially opposed to the first conductor 11 via the circuit substrate 80; the third conductor 13 in which current flows in the same direction as that in the second conductor 12, and which is provided at the back surface of the circuit substrate 80 while keeping the insulation distance D from the first conductor 11; the fourth conductor 17 which is provided at the side wall of at least one through hole 80a formed in the circuit substrate 80 and connects the second conductor 12 and the third conductor 13; the relay portion 18a filled with a thermally conductive member in the through hole 80a; and the cooling portion 16 provided at surfaces of the first conductor 11 and the third conductor 13 via the insulating thermally conductive material 15. Thus, the first conductor is opposed to the second conductor and is adjacent to the third conductor, whereby the inductance can be reduced not only at the opposed parts but also at the adjacent parts. In addition, it becomes possible to cool not only the conductor at the lower surface of the substrate but also the conductor at the front surface of the substrate via the relay portion.

### Embodiment 2

In embodiment 2, a case where the structure of the third conductor 13 in embodiment 1 is provided also on the opposite side across the first conductor 11 will be described.

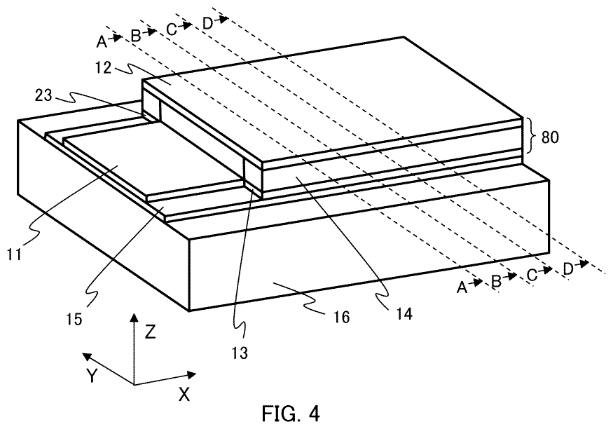

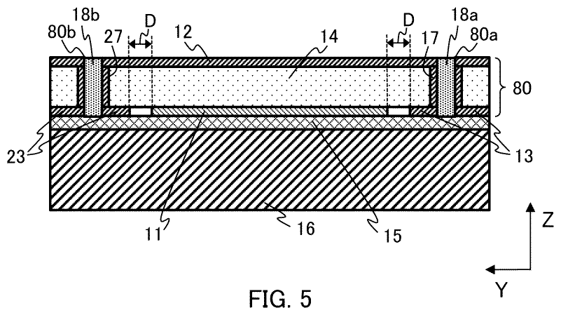

FIG. 4 is a schematic perspective view showing a configuration of a main circuit connection portion of a power conversion device according to embodiment 2. FIG. 5 is a sectional view as seen in an A-A arrow direction in FIG. 4.

As shown in FIG. 4 and FIG. 5, in the main circuit wiring portion in embodiment 2, the circuit substrate 80 has a fifth conductor 23 having the same configuration as the third conductor 13, on the side opposite to the third conductor 13 across the first conductor 11.

The fifth conductor 23 has the same potential phase (band) as the second conductor 12, and is provided at the back surface of the circuit substrate 80 which is a layer different from the second conductor 12, via the base material 14 and a relay portion 18b provided in a through hole 80b formed in the circuit substrate 80. The fifth conductor 23 is located flush with the first conductor 11, and extends on the circuit substrate 80 while keeping an insulation distance D from the first conductor 11. At least one through hole 80b is formed in the circuit substrate 80.

The first conductor 11, the third conductor 13, and a sixth conductor 27 formed at a side wall of the relay portion 80b are formed by separate members, and are electrically connected when the circuit substrate 80 is formed. Unlike a case of using a busbar with a mold, the first conductor 11 and the second conductor 12 form parallel flat plates with the comparatively thin base material 14 interposed therebetween, and therefore the distance between electrodes can be made shorter than in the case of a busbar with a mold, thus providing an effect of reducing the inductance. In addition, since the first conductor 11 and the fifth conductor 23 are located flush with each other, parallel flat plates are formed also at a side surface part, so that the inductance is further reduced.

In addition, with the above configuration, cooling efficiency for the second conductor 12 at the front surface of the circuit substrate 80 can be further improved, whereby the power conversion device can be further downsized. In addition, since the third conductor 13 and the fifth conductor 23 are located with the first conductor 11 interposed between the left and right sides, an area where parallel flat plates are present increases as compared to the configuration in embodiment 1, so that the inductance can be further reduced.

The other parts of the power conversion device 100 according to embodiment 2 are the same as those of the power conversion device 100 in embodiment 1, and the corresponding parts are denoted by the same reference characters and the description thereof is omitted.

As described above, the power conversion device 100 according to the present embodiment 2 includes, in the configuration of embodiment 1: the fifth conductor 23 in which current flows in the same direction as in the second conductor 12, and which is provided at the back surface of the circuit substrate 80 such that the first conductor 11 is interposed between the fifth conductor 23 and the third conductor 13 while keeping the respective insulation distances D from the first conductor 11; the sixth conductor 27 provided at the side wall of the through hole 80b formed in the circuit substrate 80 with the first conductor 11 interposed between the through hole 80a and the through hole 80b, the sixth conductor 27 connecting the second conductor 12 and the fifth conductor 23; and the relay portion 18b filled with a thermally conductive member in the through hole 80b. Thus, as compared to the configuration of embodiment 1, an area where parallel flat plates are present increases, so that the inductance can be further reduced. In addition, cooling efficiency can be further improved, so that the power conversion device can be further downsized.

### Embodiment 3

In embodiment 3, a case where the third conductor 13, the fifth conductor 23, and the first conductor 11 are formed over wide areas relative to the second conductor 12 in embodiment 1, will be described.

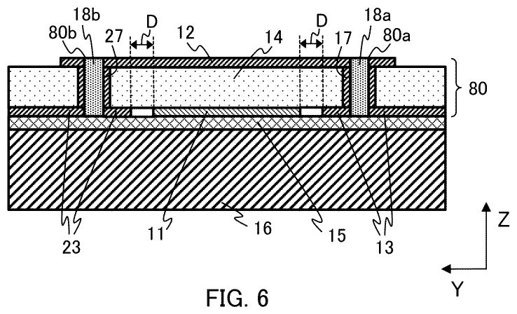

FIG. 6 is a sectional view showing a configuration of a main circuit connection portion of a power conversion device according to embodiment 3. As shown in FIG. 6, in the main circuit wiring portion in embodiment 3, the circuit substrate 80 has the third conductor 13 and the fifth conductor 23 formed over wide areas beyond the area opposed to the second conductor 12 via the circuit substrate 80.

With the above configuration, since the third conductor 13 and the fifth conductor 23 expand over wide areas on the cooling portion 16 with the insulating thermally conductive material 15 interposed therebetween, cooling performance is improved. As a result, it becomes possible to reduce the width of the second conductor 12, so that the degree of freedom in an electronic component mounting layout on the front surface of the circuit substrate 80 is improved.

The other parts of the power conversion device 100 according to embodiment 3 are the same as those of the power conversion device 100 in embodiment 2, and the corresponding parts are denoted by the same reference characters and the description thereof is omitted.

As described above, in the power conversion device 100 according to the present embodiment 3, the third conductor 13, the fifth conductor 23, and the first conductor 11 are formed over wide areas beyond the area opposed to the second conductor 12 via the circuit substrate 80. Thus, in addition to the effects of embodiment 1 and embodiment 2, these conductors expand over wide areas on the cooling portion with the insulating thermally conductive material interposed therebetween, so that cooling performance is improved. As a result, the width of the second conductor can be reduced, so that the degree of freedom in an electronic component mounting layout on the front surface of the circuit substrate is improved.

### Embodiment 4

In embodiments 1 to 3, the phases on the front surface side and the back surface side of the circuit substrate are fixed. In embodiment 4, a case where the phases are shifted to each other will be described.

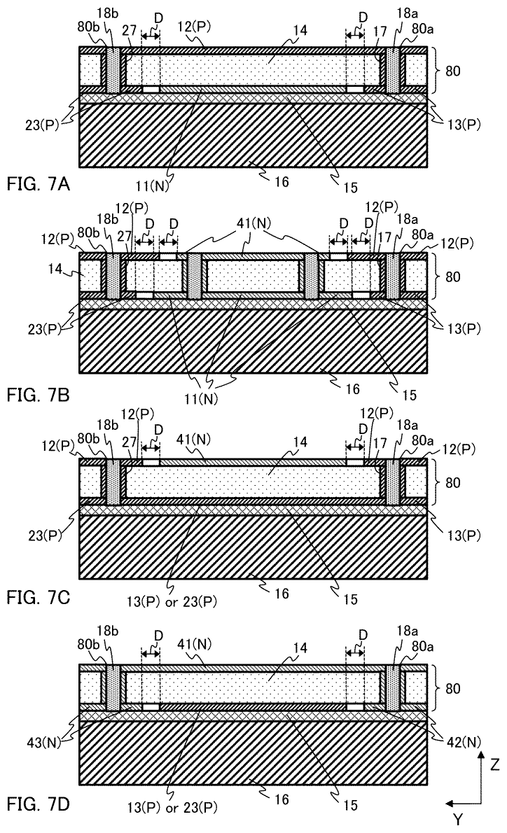

FIG. 7A to FIG. 7D are sectional views showing configurations of a main circuit connection portion of a power conversion device according to embodiment 4. FIG. 7A to FIG. 7D are sectional views as seen in directions of arrows AA, BB, CC, and DD in FIG. 4, respectively. In FIG. 7A to FIG. 7D, the potentials of the conductors are shown by (P) and (N).

As shown in FIG. 7A to FIG. 7D, in the main circuit wiring portion of embodiment 4, the circuit substrate 80 is configured such that the N phase (first conductor 11) at the back surface and the P phase (second conductor 12) at the front surface of the base material 14 are shifted to each other from the A-A position to the D-D position, and the back surface of the base material 14 is shifted to the P phase (third conductor 13 or fifth conductor 23) and the front surface of the base material 14 is shifted to the N phase (seventh conductor 41).

At the D-D position, a seventh conductor 41 is a pattern having the same potential as the first conductor 11 and is provided at a surface opposite to the first conductor 11 across the base material 14. An eighth conductor 42 and a ninth conductor 43 are patterns having the same potential as the seventh conductor 41 and are provided at a surface opposite to the seventh conductor 41 across the base material.

At the A-A position shown in FIG. 7A, the P phase (second conductor 12) is present at the front surface of the circuit substrate 80, and the N phase (first conductor 11) is present at the back surface, i.e., on the cooling portion 16 side.

At the B-B position shown in FIG. 7B, the arrangement changes from the state at the A-A position to a state in which the conductors on the front surface side and the cooling side of the circuit substrate 80 are arranged alternately in a plane direction while the insulation distances D are kept between the P phase and the N phase. As shown in FIG. 7B, the conductors are arranged in a configuration of P phase (second conductor 12 and fifth conductor 23)-N phase (seventh conductor 41 and first conductor 11)-P phase (second conductor 12 and third conductor 13). In the present embodiment 4, only the configuration of P phase-N phase-P phase is shown, but for example, the widths of P phase and N phase may be reduced and a plurality of configurations of P phase and N phase may be provided.

At the C-C position shown in FIG. 7C, the cross-section indicates that the N phase (seventh conductor 41) is transferred to the front surface side, and the P phase (second conductor 12, fifth conductor 23, and third conductor 13) is present at the front surface and a lower part.

At the D-D position shown in FIG. 7D, the N phase (seventh conductor 41) expands on the front surface of the circuit substrate 80, and also on the cooling portion 16 side, via the relay portions 18a and 18b, the N phase (eighth conductor 42 and ninth conductor 43) is formed on the same plane as the P phase (third conductor 13 or fifth conductor 23).

The states shown in FIG. 7A and FIG. 7D are states in which the P phase and the N phase are shifted to each other. In the present embodiment 4, the case where the phases are shifted to each other once has been described, but the present disclosure is not limited thereto. Between the P phase and the N phase, phase arrangements on the circuit substrate 80 may be shifted to each other a plurality of times. In the present embodiment 4, depending on the cooling condition, the areas of the eighth conductor 42, the ninth conductor 43, and the relay portions 18a and 18b can be reduced and the number of relay portions can be decreased, although not shown.

The other parts of the power conversion device 100 according to embodiment 4 are the same as those of the power conversion device 100 in embodiment 1, and the corresponding parts are denoted by the same reference characters and the description thereof is omitted.

As described above, in the power conversion device 100 according to the present embodiment 4, the circuit substrate 80 is configured such that arrangements of the potential phases of the conductors on the front surface side and the back surface side are shifted to each other at least once. Thus, the conductors for both potential phases can be directly cooled by the cooler under the circuit substrate, so that the temperature difference between the conductors is reduced. Therefore, the conductors can be cooled without excessively increasing the widths of conductor layers in order to cool high-temperature parts of the circuit substrate. Thus, the circuit substrate can be downsized, and as a result, the power conversion device can also be downsized.

### Embodiment 5

In embodiment 5, a case where metal plates are provided at conductor surfaces of the circuit substrate 80 will be described.

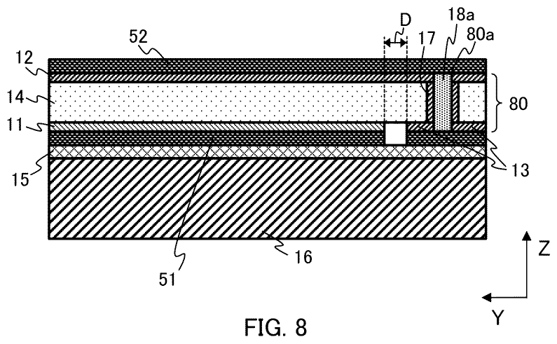

FIG. 8 is a sectional view showing a configuration of a main circuit connection portion of a power conversion device according to embodiment 5. As shown in FIG. 8, in the main circuit wiring portion in embodiment 5, a first metal plate 51 is provided at surfaces of the first conductor 11, the third conductor 13, and the relay portion 18a on the back surface of the circuit substrate 80, and a second metal plate 52 is provided at surfaces of the second conductor 12 and the relay portion 18a on the front surface of the circuit substrate 80.

The first metal plate 51 and the second metal plate 52 are mounted to the conductors by solder. In the present embodiment 5, the numbers of the first metal plate 51 and the second metal plate 52 are one, but the present disclosure is not limited thereto. The numbers and the mounting positions of the metal plates may be selected in accordance with the degree of distribution of current.

The other parts of the power conversion device 100 according to embodiment 5 are the same as those of the power conversion device 100 in embodiment 1, and the corresponding parts are denoted by the same reference characters and the description thereof is omitted.

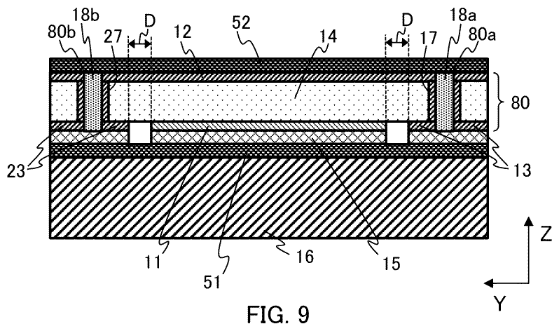

In the present embodiment 5, the case where the configuration of the third conductor 13 is provided on one side of the first conductor 11 has been described. However, this configuration may be provided also on the opposite side across the first conductor 11. FIG. 9 is a sectional view showing another configuration of the main circuit connection portion of the power conversion device according to embodiment 5. As shown in FIG. 9, in the main circuit wiring portion, the circuit substrate 80 has the fifth conductor 23 having the same configuration as the third conductor 13, on the side opposite to the third conductor 13 across the first conductor 11, and the first metal plate 51 and the second metal plate 52 are provided at the conductors, as in the above embodiment 5.

In the present embodiment 5, both of the first metal plate 51 and the second metal plate 52 are provided.

However, only one of them may be provided.

As described above, the power conversion device 100 according to the present embodiment 5 further includes one or both of the first metal plate 51 provided at the back surface of the circuit substrate 80 and the second metal plate 52 provided at the front surface of the circuit substrate 80. Thus, the metal plate provided at each conductor has an effect of increasing the sectional area of the current path, whereby the heat generation amount in each conductor can be reduced and temperature increase in each conductor can be reduced. In addition, since the thickness of each conductor increases and the sectional area thereof increases, the width of each conductor can be reduced, so that it becomes possible to reduce the area of the circuit substrate and as a result, it becomes possible to downsize the power conversion device.

### Embodiment 6

In embodiment 6, a case where the power conversion device 100 in embodiment 1 is applied to an electric vehicle will be described.

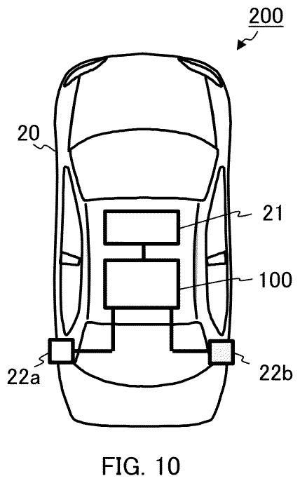

FIG. 10 shows a configuration of an electric vehicle 200 using the power conversion device 100 according to embodiment 6 of the present disclosure.

As shown in FIG. 6, the electric vehicle 200 includes: the power conversion device 100 according to each of embodiments 1 to 5, which converts DC power inputted from a battery 21 and outputs AC power; and a motor 22 (22a, 22b) which is driven with AC power inputted from the power conversion device 100.

As described above, the electric vehicle 200 using the power conversion device 100 according to the present embodiment 6 includes: the power conversion device 100 according to any one of embodiments 1 to 5, which converts DC power inputted from the battery 21 and outputs AC power; and the motor 22 (22a, 22b) which is driven with AC power inputted from the power conversion device 100. Thus, since the power conversion device is reduced in inductance and size, the electric vehicle can be reduced in size and weight.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure. It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

11 first conductor

12 second conductor
13 third conductor
15 insulating thermally conductive material
17 fourth conductor
16 cooling portion
18a, 18b relay portion
80 circuit substrate
80a, 80b through hole
100 power conversion device

1: A power conversion device comprising:
a first conductor provided at a first surface of a substrate;
a second conductor in which current flows in a direction opposite to that in the first conductor, and which is provided at a second surface of the substrate and is at least partially opposed to the first conductor via the substrate;
a third conductor in which current flows in the same direction as in the second conductor, and which is provided at the first surface of the substrate while keeping an insulation distance from the first conductor;
a fourth conductor provided at a side wall of at least one through hole formed in the substrate and connects the second conductor and the third conductor; and
a cooling portion provided at surfaces of the first conductor and the third conductor via an insulating thermally conductive material.

2: The power conversion device according to claim 1, further comprising a relay portion filled with a thermally conductive member inside the through hole.

3: The power conversion device according to claim 1, further comprising a fifth conductor in which current flows in the same direction as in the second conductor, and which is provided at the first surface of the substrate such that the first conductor is interposed between the fifth conductor and the third conductor while keeping respective insulation distances from the first conductor; and
a sixth conductor provided at a side wall of an other-side through hole formed in the substrate with the first conductor interposed between the through hole and the other-side through hole, the sixth conductor connecting the second conductor and the fifth conductor.

4: The power conversion device according to claim 3, further comprising a relay portion filled with a thermally conductive member inside the other-side through hole.

5: The power conversion device according to claim 3, wherein
the third conductor, the fifth conductor, and the first conductor are formed over wide areas beyond an area opposed to the second conductor via the substrate.

6: The power conversion device according to claim 1, wherein
the substrate is configured such that arrangements of potential phases of the first conductor and the second conductor are shifted to each other at least once.

7: The power conversion device according to claim 1, further comprising one or both of a first metal plate provided at the first surface of the substrate and a second metal plate provided at the second surface of the substrate.

8: An electric vehicle comprising:
the power conversion device according to claim 1, which converts DC power inputted from a battery and outputs AC power; and
a motor which is driven with AC power inputted from the power conversion device.

9: The power conversion device according to claim 2, further comprising a fifth conductor in which current flows in the same direction as in the second conductor, and which is provided at the first surface of the substrate such that the first conductor is interposed between the fifth conductor and the third conductor while keeping respective insulation distances from the first conductor; and
a sixth conductor provided at a side wall of an other-side through hole formed in the substrate with the first conductor interposed between the through hole and the other-side through hole, the sixth conductor connecting the second conductor and the fifth conductor.

10: The power conversion device according to claim 4, wherein
the third conductor, the fifth conductor, and the first conductor are formed over wide areas beyond an area opposed to the second conductor via the substrate.

11: An electric vehicle comprising:
the power conversion device according to claim 2, which converts DC power inputted from a battery and outputs AC power; and
a motor which is driven with AC power inputted from the power conversion device.

12: An electric vehicle comprising:
the power conversion device according to claim 3, which converts DC power inputted from a battery and outputs AC power; and
a motor which is driven with AC power inputted from the power conversion device.

13: An electric vehicle comprising:
the power conversion device according to claim 4, which converts DC power inputted from a battery and outputs AC power; and
a motor which is driven with AC power inputted from the power conversion device.

14: An electric vehicle comprising:
the power conversion device according to claim 5, which converts DC power inputted from a battery and outputs AC power; and
a motor which is driven with AC power inputted from the power conversion device.

15: An electric vehicle comprising:
the power conversion device according to claim 6, which converts DC power inputted from a battery and outputs AC power; and
a motor which is driven with AC power inputted from the power conversion device.

16: An electric vehicle comprising:
the power conversion device according to claim 7, which converts DC power inputted from a battery and outputs AC power; and
a motor which is driven with AC power inputted from the power conversion device.
